(19) United States
(12) Patent Application Publication
(10) Pub. No.: US 2019/0181383 A1
(43) Pub. Date: Jun. 13, 2019

(54) DISPLAY BACKPLATE, METHOD OF MANUFACTURING THE DISPLAY BACKPLATE AND DISPLAY DEVICE

(71) Applicants: BOE TECHNOLOGY GROUP CO., LTD., Beijing (CN); HEFEI XINSHENG OPTOELECTRONICS TECHNOLOGY CO., LTD., HEFEI (CN)

(72) Inventors: Yue HU, Beijing (CN); Chinlung LIAO, Beijing (CN); Xinxin WANG, Beijing (CN); Wenbin JIA, Beijing (CN)

(21) Appl. No.: 15/983,470

(22) Filed: May 18, 2018

(30) Foreign Application Priority Data
Dec. 11, 2017 (CN) 201711307317.X

(51) Int. Cl. H01L 51/52; H01L 27/32; H01L 51/00; H01L 51/56

(52) U.S. Cl. CPC H01L 51/5271; H01L 27/3272; H01L 27/322; H01L 2251/5315; H01L 51/0096; H01L 51/56; H01L 27/3246

(57) ABSTRACT

The present disclosure provides a display backplate, a manufacturing method thereof and a display device. A display backplate comprises: a substrate, a planar layer disposed on a first side of the substrate, a reflective layer disposed on the surface of the planar layer away from the substrate, a pixel define layer disposed on a surface of the reflective layer away from the substrate, wherein the planar layer is provided with a plurality of spaced protrusions on a surface away from of the substrate, the protrusion having a top wall and a first sidewall connected to the top wall; the reflective layer covering the first sidewall is inclined toward a light exiting direction to increase the exit angle of reflected light; an orthographic projection of the pixel define layer on the substrate overlaps an orthographic projection of the top wall of the protrusion on the substrate to define multiple pixel regions; the OLED device is located in the pixel region.

### CROSS-REFERENCE TO RELATED APPLICATIONS

The present application claims priority to Chinese Patent Application No. 201711307317.X, filed on Dec. 11, 2017, the disclosure of which is hereby incorporated by reference in its entirety.

### FIELD

This invention relates to the field of display technology, particularly to a display backplate, a method of manufacturing the display backplate and a display device.

### BACKGROUND

In the current field of display, OLED has wide application prospect due to its advantages such as high efficiency, simple fabrication processes, excellent characteristics, easy manufacturing of large size panels and full-color displays, and thus has attracted wide attention.

### SUMMARY

According to an embodiment of the present disclosure, a display backplate is provided, comprising: a substrate; a planar layer disposed on a first surface of the substrate, the planar layer being provided with a plurality of spaced protrusions on a surface away from the substrate, each of the protrusions having a top wall and a first sidewall connected to the top wall; a reflective layer disposed on the surface of the planar layer away from the substrate, the reflective layer covering the first sidewall being inclined toward a light exiting direction, thereby increasing an exit angle of reflected light; a pixel define layer disposed on a surface of the reflective layer away from the substrate, and an orthographic projection of the pixel define layer on the substrate overlapping an orthographic projection of the top wall of the protrusion on the substrate to define multiple pixel regions; and an OLED device disposed on the surface of the reflective layer away from the substrate and located in each of the pixel regions.

Optionally, the orthographic projection of the OLED device on the substrate overlaps at least a portion of an orthographic projection of the first sidewall on the substrate; or the orthographic projection of the OLED device on the substrate overlaps at least a portion of an orthographic projection of a second sidewall of the pixel define layer on the substrate and the orthographic projection of the first sidewall on the substrate.

Optionally, the display backplate may further comprise: a blocking portion disposed on the surface of the pixel define layer away from the substrate, for blocking light emitted from the OLED device in the pixel regions from toward an adjacent pixel region.

Optionally, the blocking portion may be in a hemispherical, cylindrical or cubical shape.

Optionally, a material for forming the blocking portion may include an organic material doped with a black material for light absorption.

Optionally, the protrusion may extend along a first direction.

Optionally, the protrusion may extend along a first direction and a second direction which is not parallel with the first direction.

According to another embodiment of the present disclosure, a display device is provided, comprising the display backplate according to the present disclosure described above.

Optionally, the display device may further comprise a color filter substrate disposed opposite to the display backplate, the color filter substrate comprising: a transparent substrate; and a black matrix disposed on a surface of the transparent substrate close to the display backplate, and defining openings corresponding to the pixel regions, wherein light emitted from the OLED device in one pixel region toward an adjacent pixel region is totally reflected in the color filter substrate.

Optionally, a third sidewall of the reflective layer of the display backplate, a second sidewall of the pixel define layer of the display backplate, and a fourth sidewall of the black matrix are located in a first plane, and an angle between the first plane and a normal of the transparent substrate is greater than a critical angle of the light in the color filter substrate.

According to still another embodiment of the present disclosure, a method for manufacturing a display backplate is provided, the method comprises: forming a planar layer on a first surface of the substrate, the planar layer being provided with a plurality of spaced protrusions on a surface away from the substrate, the protrusion having a top wall and a first sidewall connected to the top wall; forming a reflective layer on the surface of the planar layer away from the substrate, the reflective layer covering the first sidewall being inclined toward a light exiting direction, thereby increasing the exit angle of reflected light; forming a pixel define layer on a surface of the reflective layer away from the substrate to define multiple pixel regions, an orthographic projection of the pixel define layer on the substrate overlapping an orthographic projection of the top wall of the protrusion on the substrate; and forming an OLED device on a surface of the reflective layer away from the substrate, wherein the OLED device is located in each of the pixel regions.

Optionally, the method may further comprise: forming a blocking portion on the surface of the pixel define layer away from the substrate, the blocking portion being configured to block light emitted from the OLED device in the pixel region from toward an adjacent pixel region.

Optionally, the protrusion may extend along a first direction.

Optionally, the protrusion may extend along a first direction and a second direction which is not parallel with the first direction.

### DESCRIPTION OF THE DRAWINGS

FIG. 1 is a schematic structural view of a display backplate according to an embodiment of the present disclosure;

FIG. 2 is a schematic structural view of a display backplate according to another embodiment of the present disclosure;

FIG. 3 is a schematic structural view of a display backplate according to still another embodiment of the present disclosure;

FIG. 4 is a schematic structural view of a display backplate according to still another embodiment of the present disclosure;

FIG. 5 is a schematic structural view of a display device according to still another embodiment of the present disclosure;

FIG. 6 is a schematic structural view of a display device according to still another embodiment of the present disclosure;

FIG. 7 is a schematic structural view of a display device according to still another embodiment of the present disclosure;

FIG. 8 is a schematic structural view of a display device according to still another embodiment of the present disclosure;

FIG. 9 is a schematic diagram of a process for manufacturing a display backplate according to still another embodiment of the present disclosure;

FIG. 10 is a schematic diagram of a process for manufacturing a display backplate according to still another embodiment of the present disclosure;

FIGS. 11-13 are schematic diagrams of a process for manufacturing a display backplate according to still another embodiment of the present disclosure.

### DETAILED EMBODIMENTS

Below, embodiments of the present disclosure will be described in detail. The embodiments described below are illustrative, which are merely used to interpret the present disclosure, but cannot be understood as limitation to the present disclosure. For the specific techniques or conditions not specified in the embodiments, they are performed according to the techniques or conditions described in the literature in this field or according to the product specifications. The reagents or instruments without specified manufacturers are all available through the purchase of conventional products.

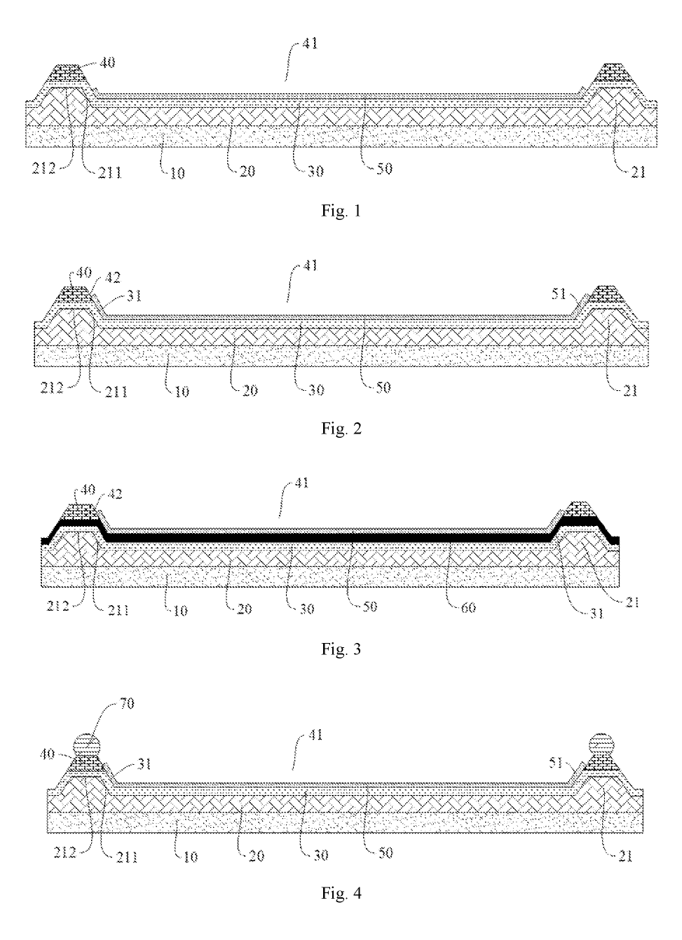

In one aspect of the present disclosure, a display backplate is provided. According to an embodiment of the present disclosure, referring to FIG. 1, the above display backplate comprises: a substrate 10; a planar layer 20 disposed on a first surface of the substrate 10, the planar layer 20 being provided with a plurality of spaced protrusions 21 on a surface away from the substrate 10, the protrusion 21 having a top wall 212 and a first sidewall 211 connected to the top wall 212; a reflective layer 30 disposed on the surface of the planar layer 20 away from the substrate 10, a portion of the reflective layer 30 covering the first sidewall 211 being inclined toward a light exiting direction, thereby increasing the exit angle of reflected light; a pixel define layer 40 disposed on a surface of the reflective layer 30 away from the substrate 10, an orthographic projection of the pixel define layer 40 on the substrate 10 overlapping an orthographic projection of the top wall 212 on the substrate 10 to define multiple pixel regions 41; an OLED device 50 disposed on a surface of the reflective layer 30 away from the substrate 10 and located in each of the pixel region 41. Thus, by providing a plurality of protrusions on the surface of the planar layer, the reflective layer disposed on the first sidewall of the protrusion is inclined toward a light exiting direction. When light emitted from the OLED device reaches the reflective layer, a portion of the light may be reflected along a direction of the first sidewall, so that the exit angle of the reflected light is increased, or the light emitted by the OLED device can directly exit along the direction of the third sidewall, which can also increase the exit angle of the light. The viewing angle of a display device with such a display backplate can be expanded. Moreover, within the visual extent of the display device, the OLED device emits light with uniform brightness, which can improve the problem of chromatic aberration at different viewing angles, resulting in a better display quality.

It should be noted that, in all the drawings of the present disclosure, a description will be provided with the sectional view of one pixel region as an example, those skilled in the art can understand that a plurality of pixel regions arranged in an array may be provided on a display backplate. The “light exiting direction” used herein refers to a light exiting direction of a display device adopting the display backplate, that is, a direction in which the display device faces a user in practical use.

According to the embodiment of the present disclosure, the specific type of the substrate is not limited, which can be flexibly selected by those skilled in the art according to practical needs, for example, including but not limited to a glass substrate, a flexible polymer substrate, etc. In some embodiments of the present disclosure, a TFT (Thin Film Transistor) array may be disposed on the substrate to meet the requirement of the display device. A specific TFT array structure can be flexibly selected by those skilled in the art according to the performance requirement of the display backplate, in which the planar layer, the pixel define layer and the OLED device are all disposed on one side of the TFT array away from the substrate.

According to an embodiment of the present disclosure, the specific material for forming the planar layer is not particularly limited, and it can be flexibly selected by those skilled in the art according to practical needs. In an embodiment of the present disclosure, the material for forming the planar layer includes, but is not limited to, silicon nitride, silicon oxide, silicon carbide, or an organic insulating material, such as a polysiloxane material, an acrylic material, or a polyimide material. Thus, a wide range of materials having high operational performance may be selected.

According to the embodiment of the present disclosure, there is no limitation on the position of the protrusions 21, as long as an effect of increasing the viewing angle can be achieved. In the embodiment of the present disclosure, referring to FIGS. 1-8, the protrusions 21 are disposed on opposite sides of each pixel region 41 (i.e., the pixel area 41 is located between two adjacent protrusions 21), and a first sidewall of the protrusion 21 is inclined toward the light exiting direction. Therefore, the viewing angle of the display device in which this display backplate is used can be maximized while guaranteeing the display effect and quality, and the OLED device can emit light evenly within a range of the visible angle of the display device, and thus the problem of chromatic aberration at different viewing angles can be effectively improved. Since a horizontal viewing angle is more commonly involved in the practical use of display devices (i.e., the user's viewing angles in left and right direction in practical use), in some embodiments of the present disclosure, the protrusions 21 are located on the left and right sides of the user during the practical use of the display backplate (that is, the protrusions 21 may extend along a first direction). Certainly, according to a practical need, the protrusions 21 may also be located on the upper and lower sides during the practical use of the display backplate (that is, the protrusions 21 may extend along a second direction), or the protrusions 21 may be provided in left and right direction and up and down direction of the user at the same time to increase the horizontal viewing angle and/or the vertical viewing angle of the display device (that is, the user's viewing angle in the up-down direction in practical use).

According to some embodiments of the present disclosure, there is no limitation on the specific shape of the protrusions 21, as long as the first sidewall thereof is inclined toward the light exiting direction. In some embodiments of the present disclosure, the cross-sectional pattern of the protrusion 21 may be trapezoidal. As a result, the effect of increasing the viewing angle can be effectively achieved, and the manufacture of the display backplate can be facilitated.

According to some embodiments of the present disclosure, the inclination of the first sidewall 211 of the protrusion 21 is also not limited, which may be flexibly specified by those skilled in the art according to actual situations such as requirement of a magnitude of the viewing angle. In some embodiments of the present disclosure, an angle between the normals of the first sidewall 211 and the substrate 10 may be flexibly adjusted within a range of greater than 0 degrees and less than 90 degrees, so as to meet the requirement of different viewing-angle ranges.

According to some embodiments of the present disclosure, in order to use the light more efficiently and increase brightness in the light exiting direction, referring to FIG. 1, a reflective layer 30 is provided on the surface of the planar layer for reflecting light toward the light exiting direction. According to some embodiments of the present disclosure, the material for forming the reflective layer is not limited, as long as it has a high reflectance. In some embodiments of the present disclosure, the material for forming the reflective layer is a metal such as aluminum, magnesium, silver, and the like or an alloy thereof. Thus, the reflective layer may be formed using a wide range of materials, having a high reflectance, good conductivity, and high operational performance.

According to some embodiments of the present disclosure, the material for forming the pixel define layer is not particularly limited, which can be flexibly selected by those skilled in the art according to practical situations. In some embodiments of the present disclosure, the material for forming the pixel define layer includes, but is not limited to, silicon nitride, silicon oxide, silicon oxynitride, or an organic insulating material, such as a polysiloxane material or an acrylic material. Thus, a wide range of materials having low cost and good operational performance can be used.

According to the embodiment of the present disclosure, due to the protrusions disposed on the planar layer, the edge of the OLED device may also be correspondingly inclined toward the light exiting direction. Specifically, in some embodiments of the present disclosure, referring to FIG. 1, an orthographic projection of the OLED device 50 on the substrate 10 overlaps at least a portion of an orthographic projection of the first sidewall 211 on the substrate 10. In some other embodiments of the present disclosure, referring to FIG. 2, the orthographic projection of the OLED device 50 on the substrate 10 overlaps the orthographic projection of the first sidewall 211 on the substrate 10 and at least a portion of an orthographic projection of a second sidewall 42 of the pixel define layer 40 on the substrate 10. That is, the edge of the OLED device may cover at least a portion of the first sidewall 211, or cover the first sidewall and at least a portion of the second sidewall of the pixel define layer. Thus, the edge portion 51 of the OLED device may be inclined toward the light exiting direction to emit light at a larger exit angle. Further, the inclined edge portion is naturally formed by the protrusions on the planar layer, so that the manufacturing process of the OLED device does not need any additional adjustment and may be implemented by a conventional process that is easy to implement, simple in operation, and has a low cost. Moreover, when light emitted from the OLED device reaches a third sidewall 311 of the reflective layer, the light is reflected by the reflective layer and exits along the direction of the third sidewall, or the light emitted by the OLED device can directly exit along the direction of the third sidewall 311, which can increase the exit angle of the reflected light, so that the viewing angle of a display device in which the display backplate is adopted can be expanded. Moreover, in the visual extent of the display device, the OLED device emits light with uniform brightness, which can improve the problem of chromatic aberration at different viewing angles, resulting in a better display quality.

According to some embodiments of the present disclosure, the specific structure of the OLED device is not particularly limited, and can be flexibly selected by those skilled in the art according to needs, as long as the use requirement may be satisfied. In some embodiments of the present disclosure, the OLED device may include a first electrode, a second electrode, and a light emitting layer disposed between the first electrode and the second electrode. In some further embodiments of the present disclosure, the OLED device may include a first electrode, a second electrode, a light emitting layer disposed between the first electrode and the second electrode, and at least one of an electron injection layer, an electron transport layer, a hole transport layer, or a hole injection layer disposed between the light emitting layer and the first electrode or the second electrode. Thereby, a better display effect can be achieved.

According to the embodiment of the present disclosure, the specific arrangement of the various film layers in the OLED device is not particularly limited, as long as it can guarantee normal light emission of the OLED device. In some embodiments of the present disclosure, in order to further simplify the manufacturing process, referring to FIG. 3, the first electrodes of the OLED devices 50 in the plurality of pixel regions may collectively constitute a plane electrode 60 disposed on one surface of the reflective layer 30 away from the substrate 10. Due to the protrusions provided on the planar layer, the plane electrode can be inclined toward the light exiting direction accordingly, so as to achieve an effect of increasing the exit angle of light, thereby expanding the viewing angle of a display device in which this display backplate is adopted.

According to some embodiments of the present disclosure, as described above, due to the presence of the protrusions, the irradiation range of the light emitted by the OLED device is expanded. As a result, with a sufficient large exit angle of the light, an adjacent pixel region may be irradiated, so that undesirable phenomenons such as light leakage may occur (light leakage mainly refers to lighting a pixel region that does not need to emit light due to light transmission), thereby affecting the display quality of the display device. Further, referring to FIG. 4, the display backplate may further comprise: a blocking portion 70 disposed on the surface of the pixel define layer 40 away from the substrate 10, and configured to block light emitted from the OLED device 50 in one pixel region from transmitting toward an adjacent pixel region, so as to prevent light leakage. Therefore, the blocking portion may block the light emitted from an OLED device in one pixel region from transmitting toward its adjacent pixel region so as to prevent the pixel region adjacent to the OLED device from being illuminated and causing light leakage, which otherwise may affect the display effect of the display device.

According to some embodiments of the present disclosure, there is no limitation on the shape of the blocking portion as long as it can block the light emitted from the OLED device from transmitting toward its adjacent pixel region. In some embodiments of the present disclosure, the blocking portion is hemispherical (see FIG. 4), columnar (not shown), or cubic (not shown). Therefore, a better blocking effect can be achieved to effectively avoid the light leakage phenomenon, and the display quality of the display device can be improved.

According to some embodiments of the present disclosure, the material for forming the blocking portion is not particularly limited, and can be flexibly selected by those skilled in the art according to practical situations. In some embodiments of the present disclosure, the material for forming the blocking portion includes an organic material doped with a black material for light absorbing. Thus, the blocking portion can absorb light emitted from the OLED device and transmitting toward its adjacent pixel region to prevent light leakage, so that the display effect of the display device can be improved.

According to the embodiment of the present disclosure, there is no limitation on the size of the blocking portion, and it can be designed by those skilled in the art according to the practical situations such as the size and inclination of a slope portion, which is not limited herein.

In another aspect of the present disclosure, a display device is provided. According to some embodiments of the present disclosure, the display device comprises the display backplate described above. Therefore, the display device has a large viewing angle, a good display quality, without chromatic aberration at different viewing angles, and has strong market competitiveness. In addition, the display device has all the features and advantages of the display backplate described above, which will not be repeated in detail herein.

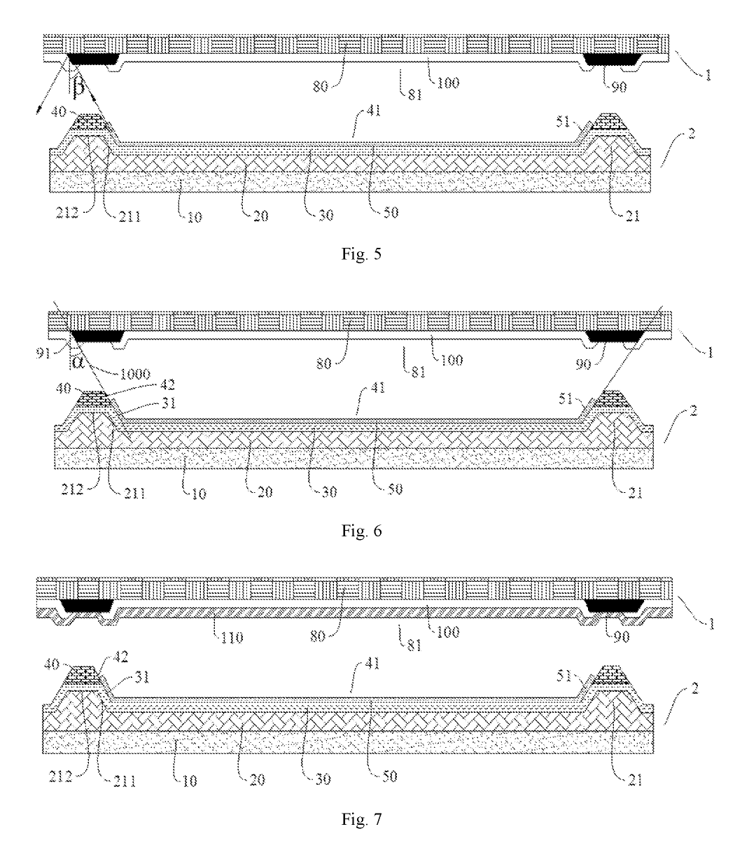

According to some embodiments of the present disclosure, referring to FIG. 5, the display device further includes a color filter substrate 1 disposed opposite to the display backplate 2. The color filter substrate 1 includes: a transparent substrate 80; a black matrix 90 disposed on a surface of the transparent substrate 80 close to the display backplate 2, and defining openings 81 corresponding to the pixel regions 41. Light emitted from the OLED device 50 in one pixel region and transmitting toward an adjacent pixel region is totally reflected when passing through the color filter substrate 1. Therefore, by adopting the display backplate described above, the viewing angle of the display device can be enlarged, and the OLED device can have uniform brightness in the visual extent of the display device, which can improve the problem of chromatic aberration at different viewing angles, resulting in a better display quality. In addition, when a portion of light reflected from the second sidewall of the reflective layer or a portion of light emitted by the OLED device is transmitted toward an adjacent pixel region, this portion of light may be totally reflected on a surface of the transparent substrate when passing through the color filter substrate, i.e., it is reflected back into the OLED device and then reused after reflection by the reflective layer, so that the utilization of light can be increased, light leakage can be effectively avoided, and the display quality can be improved.

According to some embodiments of the present disclosure, depending on the color of light emitted from the OLED device, those skilled in the art can select whether to provide a color filter on the color filter substrate. Specifically, in a case of an OLED device emitting white light or blue light, in order to realize color display, referring to FIG. 5, the color filter substrate further includes a color filter layer 100 to achieve the display effect of the display device. If the OLED devices in different pixel regions emit light of different colors, for example, if the OLED devices emit red, green, and blue light respectively, color display can be achieved without the need of providing color filters (not shown) on the color filter substrate.

According to some embodiments of the present disclosure, the materials for forming the transparent substrate, the black matrix, and the color filter is not limited and can be flexibly selected by those skilled in the art according to the actual situations, which are not limited herein.

According to a specific embodiment of the present disclosure, referring to FIG. 5, taking a green sub-pixel of 80 ppi as an example, the pixel width is 51 the refractive index of the transparent substrate is 1.51, the refractive index of air is 1, and the total reflection angle at which light is transmitted toward the air through the transparent substrate is 41°. Thus if the incident angle β of the light emitted toward the adjacent pixel region is greater than 41° when it is passing through the color filter substrate, the light can be totally reflected on the surface of the transparent substrate. That is, it can be ensured that the light emitted by the OLED device in one pixel region will not reach its adjacent pixel region, so that the light leakage phenomenon can be effectively prevented and the display quality can be improved.

According to the embodiment of the present disclosure, as described above, in order to enable total reflection of the light emitted toward the adjacent pixel region at the time of passing through the color filter substrate, i.e. the light emitted from the OLED device in one pixel region toward its adjacent pixel region, incident angle of the light which transmitted toward the transparent substrate through the color filter substrate must be greater than the critical angle at which the light can pass through the color filter substrate and exit from the transparent substrate. Specifically, the above requirement can be achieved by adjusting the inclined angle of the reflective layer covering the first sidewall, the angle of the second sidewall of the pixel define layer, the angle of the fourth sidewall of the black matrix. In some embodiments of the present disclosure, referring to FIG. 6, a third sidewall 31 of the reflective layer 30 in the display backplate, a second sidewall 42 of the pixel defining layer 40 in the display backplate, and a fourth sidewall 91 of the black matrix 90 may be designed to be located in a first plane 1000, and the angle a between the first plane 1000 and the normal of the transparent substrate 80 is greater than the critical angle when light is emitted through the color filter substrate. Therefore, not only can it be ensured that the adjacent pixel region cannot be illuminated by the light emitted from the OLED device to prevent light leakage, but also the display device can have the largest viewing angle, with uniform brightness of the display device in a viewing-angle range, so that the problem of chromatic aberration at different viewing angles may be significantly weakened, and a good display effect can be achieved.

It should be noted that, for one pixel region, the “first sidewall”, “second sidewall”, “third sidewall”, and “fourth sidewall” used in the description herein refer to a sidewall of the protrusion on the planar layer close to the OLED device in the pixel region, a sidewall of the pixel define layer close to the OLED device in the pixel region, a surface of the reflective layer away from the substrate and covering the first sidewall of the protrusion, and a sidewall of the black matrix away from the OLED device in the pixel region respectively.

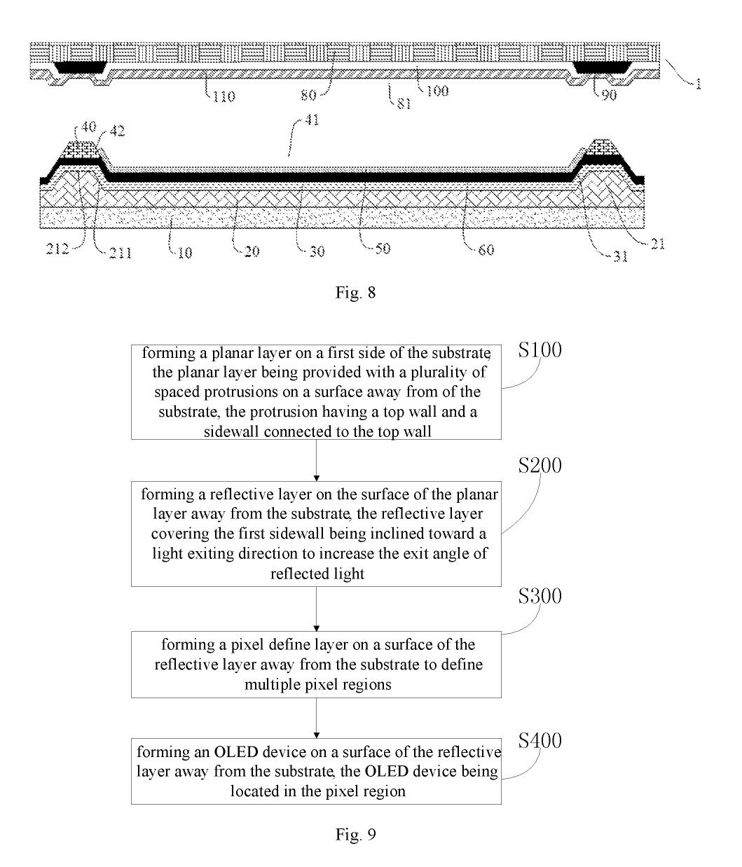

According to an embodiment of the present disclosure, in order to further improve the operational performance of the display device, referring to FIG. 7 and FIG. 8 , the display device may further include a protective layer 110 disposed on one side of the color filter 100 away from the transparent substrate and covering the black matrix. Thereby, the operational performance of the display device can be improved.

According to the embodiment of the present disclosure, the specific type of the display device is not particularly limited. It may be any device or apparatus in the art having a display function. For example, it may include but not limited to a mobile phone, a tablet computer, a computer display, a game console, a TV set, a display screen, a wearable device, and any home appliance, living appliance with a display function.

Of course, those skilled in the art can understand that, in addition to the display backplate as described above, the display device described in the present disclosure may also include the necessary structures and components that a conventional display device may have. Taking a mobile phone as an example, in addition to the backlight display backplate of the present disclosure, it can also have the structures and components of a conventional mobile phone such as a touch screen, a housing, a CPU, a camera module, a fingerprint recognition module, a sound processing system, etc, which will not be described in detail herein.

In yet another aspect of the present disclosure, the present disclosure provides a method of manufacturing a display backplate. Referring to FIG. 9, the method includes

S100: forming a planar layer on a first surface of the substrate, the planar layer being provided with a plurality of spaced protrusions on a surface away from the substrate, the protrusion having a top wall and a sidewall connected to the top wall.

According to an embodiment of the present disclosure, the method of forming the planar layer is not particularly limited, and it can be flexibly selected by those skilled in the art according to practical needs. In some embodiments of the present disclosure, the method of forming the planar layer includes, but is not limited to, chemical vapor deposition or physical vapor deposition, etching, etc. Thus, its process is mature and easy for industrial production.

According to an embodiment of the present disclosure, an insulating layer having a planar surface may be formed by chemical vapor deposition or physical vapor deposition, and then protrusions may be formed on a surface of the insulating layer away from the substrate by etching, and the planar layer is formed. Thus, its process is mature and easy for industrial production.

S200: forming a reflective layer on a side of the planar layer away from the substrate, the reflective layer covering the first sidewall being inclined toward a light exiting direction, thereby increasing the exit angle of reflected light.

According to an embodiment of the present disclosure, the method of forming the reflective layer is not particularly limited, and it can be flexibly selected by those skilled in the art according to practical needs. In some embodiments of the present disclosure, the method of forming the reflective layer includes, but is not limited to, chemical vapor deposition or physical vapor deposition. Thus, its process is mature and easy for industrial production.

It should note that since a protrusion is provided on the planar layer, when a reflective layer is deposited on the surface of the planar layer away from the substrate, the reflective layer covering the first sidewall of the protrusion is naturally inclined to the light exiting direction, thus the effect of increasing the exit angle of the reflected light may be achieved without any additional adjustment to a process of forming a reflective layer.

S300: forming a pixel define layer on a surface of the reflective layer away from the substrate to define multiple pixel regions, an orthographic projection of the pixel define layer on the substrate overlapping an orthographic projection of the top wall of the protrusion on the substrate.

According to the embodiment of the present disclosure, the material for forming the pixel define layer is not particularly limited, which can be flexibly selected by those skilled in the art according to practical situations. In some embodiments of the present disclosure, the method of forming the pixel define layer includes, but is not limited to, chemical vapor deposition or physical vapor deposition, etching, etc. Thus, its process is mature and easy for industrial production. Specifically, an entire insulating layer may be deposited in advance, then a plurality of pixel regions may be defined by an etching process, and the pixel define layer is formed.

S400: forming an OLED device on a surface of the reflective layer away from the substrate, the OLED device is located in the pixel region, as shown in FIGS. 1-3.

According to an embodiment of the present disclosure, the method for forming the OLED device is not particularly limited, Those skilled in the art can flexibly select any method applicable in the field according to practical situations, for example, chemical vapor deposition (such as vapor deposition) or physical vapor deposition can be used, which is not limited herein.

According to some embodiments of the present disclosure, the above manufacturing method is simple and easy for industrial production. In the above method, through providing a plurality of protrusions on the surface of the planar layer to incline the reflective layer disposed on the first sidewall of the protrusion toward a light exiting direction, when the light emitted from the OLED device reaches the reflective layer, it may be reflected along the direction of the first sidewall, or the light emitted by the OLED device can directly exit along the direction of the third sidewall, so that the exit angle of the light may be increased and the viewing angle of a display device in which the display backplate is adopted can be expanded. Moreover, in the visual extent of the display device, the OLED device emits light with uniform brightness, which can improve the problem of chromatic aberration at different viewing angles, resulting in a better display quality.

According to an embodiment of the present disclosure, the above method may be used to manufacture the display backplate described above. Wherein, the substrate, the planar layer, the pixel define layer, and the OLED device may be the same as described above, and will not be described in detail herein.

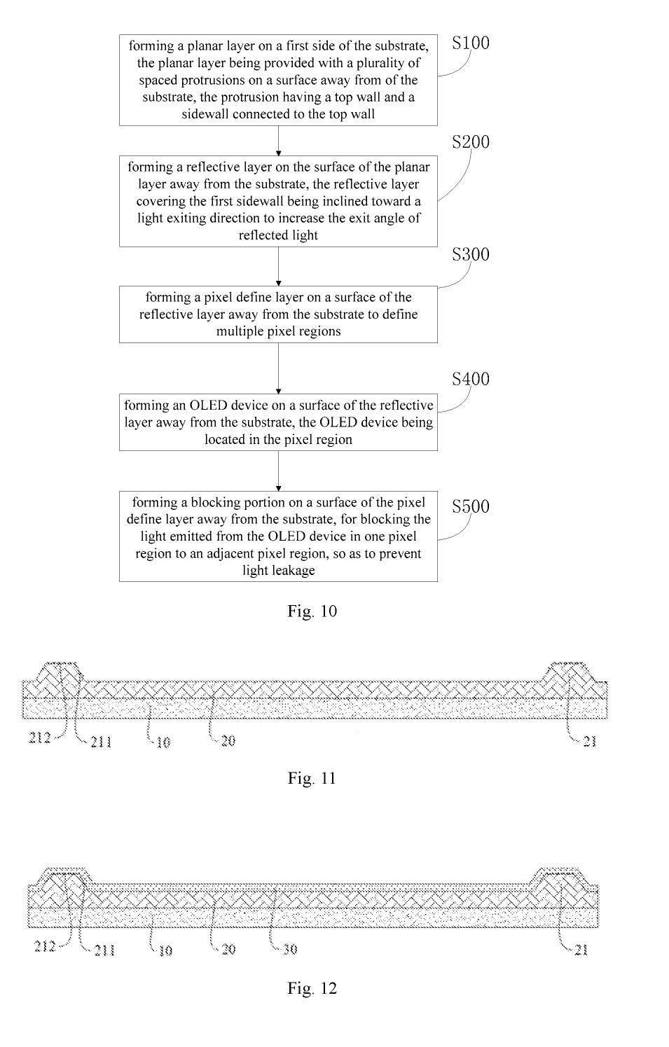

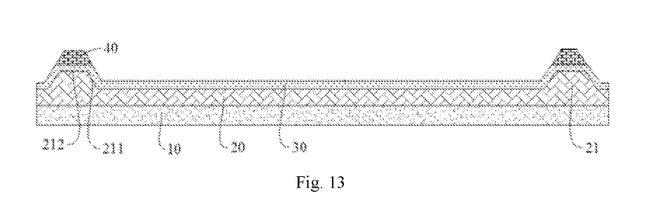

According to an embodiment of the present disclosure, referring to FIG. 10, the above method further includes:

S500: forming a blocking portion on a surface of the pixel define layer away from the substrate, for blocking the light emitted from the OLED device in one pixel region from toward an adjacent pixel region, so as to prevent light leakage, as shown in FIG. 4. Therefore, the blocking portion may block the light which is emitted from an OLED device in one pixel region and transmits toward its adjacent pixel region, so as to prevent the pixel region adjacent to the OLED device from being illuminated or causing light leakage, which otherwise may affect the display effect of the display device.

According to an embodiment of the present disclosure, the specific material for forming the blocking portion is not particularly limited, and it can be flexibly selected by those skilled in the art according to practical needs. In some embodiments of the present disclosure, the method of forming the blocking portion includes, but is not limited to, precisely placing a spherical, cylindrical or cubic blocking portion in a determined area directly using a robot; or mixing a material for blocking (such as black particles, etc.) in a photoresist and etching to obtain a blocking portion having a corresponding shape by an etching process.

According to the embodiment of the present disclosure, the material, size and shape of the blocking portion are the same as those described above, and will not be repeated herein.

In yet another aspect of the present disclosure, the present disclosure provides a method of manufacturing the display device described above. According to an embodiment of the present disclosure, the method includes the above method of manufacturing a display backplate, and further includes a step of forming a color filter substrate, wherein the color filter substrate 1 includes: a transparent substrate 80; a black matrix 90 disposed on a surface of the transparent substrate 80 close to the display backplate 2, and defining openings 81 corresponding to the pixel regions 41, wherein light emitted from the OLED device 50 in one pixel region and toward its adjacent pixel region is totally reflected when passing through the color filter substrate 1, as shown in FIG. 5. Therefore, by adopting the display backplate described above, the viewing angle of the display device can be enlarged, and the OLED device can have uniform brightness in the visual extent of the display device, which can improve the problem of chromatic aberration at different viewing angles, resulting in a better display quality. In addition, when the light emitted from the OLED device in one pixel region and transmitted toward its adjacent pixel region passes through the color filter substrate, it is totally reflected on the surface of the transparent substrate, i.e., it is reflected back to the OLED device and then reused after reflection by the reflective layer, so that the utilization of light can be increased, light leakage can be effectively avoided, and the display quality can be improved.

According to the embodiment of the present disclosure, there is no limitation on the specific method for forming the color filter substrate. Those skilled in the art can select the conventional technical means in the art, and no limitation is imposed herein.

According to the embodiment of the present disclosure, as described above, in order to enable total reflection of the light emitted to the adjacent pixel area passing through the color filter substrate, the incident angle of the light emitted from the OLED device in one pixel area to its adjacent pixel region passing through the color filter substrate and reaching the transparent substrate must be greater than the critical angle at which the light can pass through the color filter substrate and exit from the transparent substrate. Specifically, in the manufacturing process, the above requirement can be achieved by adjusting the angle of the inclined portion of the OLED device, the angle of the sidewall of the protrusion on the planar layer, and the angle of the sidewall of the pixel define layer. In some embodiments of the present disclosure, referring to FIG. 6, a third sidewall 31 of the reflective layer 30 in the display backplate, a second sidewall 42 of the pixel defining layer 40 in the display backplate, and a fourth sidewall 91 of the black matrix 90 may be designed to be located in a first plane 1000, and the angle a between the first plane 1000 and the normal line of the transparent substrate 80 is greater than the critical angle when light is emitted through the color filter substrate. Therefore, not only can it be ensured that the adjacent pixel region cannot be irradiated by the light emitted from the OLED device to prevent light leakage, but also the display device can have the largest viewing angle, with uniform brightness of the display device in a viewing-angle range, so that the problem of chromatic aberration at different viewing angles may be significantly weakened, and a good display effect can be achieved.

In the description of this specification, reference throughout this specification to “one embodiment”, “some embodiments”, “illustrative embodiments”, “examples”, “specific examples”, or “some examples” means that a particular feature, structure, material or characteristic described in connection with the embodiment is included in at least one embodiment of the present invention. Therefore, illustrative references to the above terms in various portions of this specification are not necessarily all referring to the same embodiment or example. Furthermore, the particular features, structures, materials or characteristics may be combined as suitable in one or more embodiments of the invention. In addition, those skilled in the art may combine the different embodiments or examples described in this specification and features of different embodiments or examples without conflicting with each other.

Although embodiments of the present disclosure have been illustrated and described above, it will be understood that the above-described embodiments are exemplary and not to be construed as limiting the present disclosure. Those of ordinary skill in the art may make variations, modifications, substitutions, and variations to the above described embodiments within the scope of the present disclosure.

1. A display backplate, comprising:
a substrate;
a planar layer disposed on a first surface of the substrate, the planar layer being provided with a plurality of spaced protrusions on a surface away from the substrate, each of the plurality of spaced protrusions having a top wall and a first sidewall connected to the top wall;
a reflective layer disposed on the surface of the planar layer away from the substrate, the reflective layer covering the first sidewall being inclined toward a light exiting direction, thereby increasing an exit angle of reflected light;
a pixel define layer disposed on a surface of the reflective layer away from the substrate, and an orthographic projection of the pixel define layer on the substrate overlapping an orthographic projection of the top wall of the protrusion on the substrate to define multiple pixel regions; and
an OLED device disposed on the surface of the reflective layer away from the substrate and located in each of the multiple pixel regions.

2. The display backplate according to claim 1, wherein the orthographic projection of the OLED device on the substrate overlaps with:
at least a portion of an orthographic projection of the first sidewall on the substrate, or at least a portion of an orthographic projection of a second sidewall of the pixel define layer on the substrate and the orthographic projection of the first sidewall on the substrate.

3. The display backplate according to claim 1, further comprising:
a blocking portion disposed on the surface of the pixel define layer away from the substrate, for blocking light emitted from the OLED device in each of the multiple pixel regions from toward a respective adjacent pixel region.

4. The display backplate according to claim 3, wherein the blocking portion is in a hemispherical, cylindrical or cubical shape.

5. The display backplate according to claim 3, wherein a material for forming the blocking portion includes an organic material doped with a black material for light absorption.

6. The display backplate according to claim 1, wherein the protrusions extend along a first direction.

7. The display backplate according to claim 1, wherein the protrusions extend along a first direction and a second direction which is not parallel with the first direction.

8. A display device, comprising the display backplate according to claim 1.

9. The display device according to claim 8, further comprising a color filter substrate disposed opposite to the display backplate, the color filter substrate comprising:
a transparent substrate; and
a black matrix disposed on a surface of the transparent substrate close to the display backplate, and defining openings corresponding to the multiple pixel regions,
wherein light emitted from the OLED device in one pixel region toward an adjacent pixel region is totally reflected in the color filter substrate.

10. The display device according to claim 8, wherein a third sidewall of the reflective layer of the display backplate, a second sidewall of the pixel define layer of the display backplate, and a fourth sidewall of the black matrix are located in a first plane, and an angle between the first plane and a normal of the transparent substrate is greater than a critical angle of the light in the color filter substrate.

11. A method for manufacturing a display backplate, comprising:
forming a planar layer on a first surface of a substrate, the planar layer being provided with a plurality of spaced protrusions on a surface away from the substrate, each of the plurality of spaced protrusions having a top wall and a first sidewall connected to the top wall;
forming a reflective layer on the surface of the planar layer away from the substrate, the reflective layer covering the first sidewall being inclined toward a light exiting direction, thereby increasing an exit angle of reflected light;
forming a pixel define layer on a surface of the reflective layer away from the substrate to define multiple pixel regions, an orthographic projection of the pixel define layer on the substrate overlapping an orthographic projection of the top wall of the protrusion on the substrate; and
forming an OLED device on a surface of the reflective layer away from the substrate, wherein the OLED device is located in each of the multiple pixel regions.

12. The method according to claim 11, further comprising:
forming a blocking portion on the surface of the pixel define layer away from the substrate, the blocking portion being configured to block light emitted from the OLED device in each of the multiple pixel regions from toward a respective adjacent pixel region.

13. The method according to claim 11, wherein the plurality of spaced protrusions extend along a first direction.

14. The method according to claim 11, wherein the plurality of spaced protrusions extend along a first direction and a second direction which is not parallel with the first direction.
